(19) United States
(12) Patent Application Publication
(10) Pub. No.: US 2024/0334683 A1
(43) Pub. Date: Oct. 3, 2024

(54) MEMORY DEVICES AND METHODS OF FORMING THE SAME

(71) Applicant: Applied Materials, Inc., Santa Clara, CA (US)

(72) Inventors: Tong Liu, Folsom, CA (US); Sony Varghese, Manchester, MA (US); Zhijun Chen, San Jose, CA (US); Balasubramanian Pranatharthiharan, San Jose, CA (US); Anand N. Iyer, Fremont, CA (US)

(73) Assignee: Applied Materials, Inc., Santa Clara, CA (US)

(21) Appl. No.: 18/613,525

(22) Filed: Mar. 22, 2024

Related U.S. Application Data
(60) Provisional application No. 63/456,637, filed on Apr. 3, 2023.

(51) Int. Cl. H10B 12/00

(52) U.S. Cl. CPC H10B 12/482; H10B 12/02

(57) ABSTRACT

Memory devices and methods of manufacturing memory devices are described herein. The memory devices include a bitline metal stack on a surface comprising a matrix of conductive bitline contacts (e.g., polysilicon) and insulating dielectric islands (e.g., silicon nitride (SiN)). The bitline metal stack comprises one or more of titanium (Ti), tungsten (W), tungsten nitride (WN), tungsten silicide (WS), or tungsten silicon nitride (WSiN). The memory devices include a bitline metal layer (e.g., tungsten (W)) on a top surface of the insulating dielectric islands and on the bitline metal stack.

### CROSS-REFERENCE TO RELATED APPLICATIONS

This application claims priority to U.S. Provisional Application No. 64/456,637, filed Apr. 3, 2023, the entire disclosure of which is hereby incorporated by reference herein.

### TECHNICAL FIELD

Embodiments of the present disclosure pertain to the field of electronic devices and methods and apparatus for manufacturing electronic devices. More particularly, embodiments of the disclosure provide memory devices and methods for forming memory devices having reduced bitline metal stack thickness and reduced bitline capacitance.

### BACKGROUND

Electronic devices, such as personal computers, workstations, computer servers, mainframes, and other computer related equipment such as printers, scanners and hard disk drives use memory devices that provide substantial data storage capability, while incurring low power consumption. There are two major types of random-access memory cells, dynamic and static, which are well-suited for use in electronic devices. Dynamic random-access memories (DRAMs) can be programmed to store a voltage which represents one of two binary values, but require periodic reprogramming or “refreshing” to maintain this voltage for more than very short periods of time. Static random-access memories (SRAMs) are so named because they do not require periodic refreshing.

DRAM memory circuits are manufactured by replicating millions of identical circuit elements, known as DRAM cells, on a single semiconductor wafer. Each DRAM cell is an addressable location that can store one bit (binary digit) of data. In its most common form, a DRAM cell consists of two circuit components: a field effect transistor (FET) and a capacitor.

The manufacturing of a DRAM cell includes the fabrication of a transistor, a capacitor, and contacts to the bitline and to the wordline. DRAM manufacturing is a highly competitive business. There is continuous pressure to decrease the size of individual cells and to increase memory cell density to allow more memory to be squeezed onto a single memory chip, especially for densities greater than 256 Megabits. Limitations on cell size reduction include the passage of both active and passive word lines through the cell, the size of the cell capacitor, and the compatibility of array devices with nonarray devices.

Bitline capacitance is a critical parameter for DRAM cells and a low bitline capacitance is desired. The bitline metal stack consists of a metal and a barrier metal stack. The barrier metal stack thickness accounts for 20%-30% of the bitline metal stack thickness, and the overall thickness of bitline metal stack determines the bitline capacitance. Typically, a thin bitline metal stack provides a low bitline capacitance. However, reducing the metal thickness usually causes high line resistance, especially with aggressively scaled bitline critical dimensions (CD).

Therefore, there is a need in the art for memory devices and methods of forming memory devices that have reduced bitline metal stack thickness and reduced bitline capacitance without increasing line resistance.

### SUMMARY

One or more embodiments of the disclosure are directed to a method of forming a memory device. The method includes depositing a bitline metal stack on a surface comprising a matrix of conductive bitline contacts and insulating dielectric islands; etching a portion of the bitline metal stack to expose a top surface of the insulating dielectric islands; and depositing a bitline metal layer on the top surface of the exposed insulating dielectric islands and on the bitline metal stack to form a plurality of bitlines.

Further embodiments of the disclosure are directed to methods of forming a memory device. The methods include selectively depositing a bitline metal stack on a surface comprising a matrix of conductive bitline contacts and insulating dielectric islands. The bitline metal stack selectively deposits on the conductive bitline contacts relative to the insulating dielectric islands. The methods further include depositing a bitline metal layer on a top surface of the insulating dielectric islands and on the bitline metal stack to form a plurality of bitlines.

Additional embodiments of the disclosure are directed to a memory device. In one or more embodiments, a memory device comprises a bitline metal stack on a surface comprising a matrix of conductive bitline contacts and insulating dielectric islands. In some embodiments, the bitline metal stack comprises one or more of titanium (Ti), tungsten (W), tungsten nitride (WN), tungsten silicide (WS), or tungsten silicon nitride (WSiN), and has a thickness in a range of from about 50 Å to about 100 Å. The memory device further includes a bitline metal layer on a top surface of the insulating dielectric islands and on the bitline metal stack. In some embodiments, the bitline metal layer comprises tungsten (W) and has a thickness in a range of from about 150 Å to about 250 Å.

### BRIEF DESCRIPTION OF THE DRAWING

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1A illustrates a process flow diagram of a method of forming a memory device according to one or more embodiments;

FIG. 1B illustrates a process flow diagram of a method of forming a memory device according to one or more embodiments;

FIG. 2A illustrates a top view of a memory device according to one or more embodiments;

FIG. 2B illustrates a cross-sectional view of the memory device of FIG. 2A taken along line A-A′;

FIG. 3A illustrates a top view of a memory device according to one or more embodiments

FIG. 3B illustrates a cross-sectional view of the memory device of FIG. 3A taken along line A-A′;

FIG. 4A illustrates a top view of a memory device according to one or more embodiments;

FIG. 4B illustrates a cross-sectional view of the memory device of FIG. 4A taken along the line A-A′;

FIG. 5A illustrates a top view of a memory device according to one or more embodiments;

FIG. 5B illustrates a cross-sectional view of the memory device of FIG. 5A taken along the line A-A′;

FIG. 6A illustrates a top view of a memory device according to one or more embodiments;

FIG. 6B illustrates a cross-sectional view of the memory device of FIG. 6A taken along the line A-A′;

FIG. 6C illustrates a cross-sectional view of the memory device of FIG. 6A taken along the line B-B′;

FIG. 6D illustrates a cross-sectional view of the memory device of FIG. 6A taken along the line C-C′;

FIG. 7A illustrates a top view of a memory device according to one or more embodiments;

FIG. 7B illustrates a cross-sectional view of the memory device of FIG. 7A taken along the line A-A′;

FIG. 8A illustrates a top view of a memory device according to one or more embodiments;

FIG. 8B illustrates a cross-sectional view of the memory device of FIG. 8A taken along the line A-A′;

FIG. 9A illustrates a top view of a memory device according to one or more embodiments;

FIG. 9B illustrates a cross-sectional view of the memory device of FIG. 9A taken along the line A-A′;

FIG. 10A illustrates a top view of a memory device according to one or more embodiments;

FIG. 10B illustrates a cross-sectional view of the memory device of FIG. 10A taken along the line A-A′;

FIG. 10C illustrates a cross-sectional view of the memory device of FIG. 10A taken along the line B-B′;

FIG. 10D illustrates a cross-sectional view of the memory device of FIG. 10A taken along the line C-C′; and

FIG. 11 illustrates a cluster tool according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the terms “precursor,” “reactant,” “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction). The substrate, or portion of the substrate, is exposed to the precursors (or reactive gases) sequentially or substantially sequentially. As used herein throughout the specification, “substantially sequentially” means that a majority of the duration of a precursor exposure does not overlap with the exposure to a co-reagent, although there may be some overlap.

The term “over” as used herein does not imply a physical orientation of one surface on top of another surface, rather a relationship of the thermodynamic or kinetic properties of the chemical reaction with one surface relative to the other surface. For example, selectively depositing a bitline metal stack on conductive bitline contacts over the insulating dielectric islands means that the bitline metal stack deposits on the conductive bitline contacts and less or no bitline metal stack deposits on the insulating dielectric islands; or that the formation of the bitline metal stack on the conductive bitline contacts is thermodynamically or kinetically favorable relative to the formation of the bitline metal stack on the insulating dielectric islands.

The term “relative” may also be used to describe a relationship of the thermodynamic or kinetic properties of the chemical reaction with one surface relative to the other surface. Therefore, in this regard, the terms “over” and “relative” can be used interchangeably unless the context indicates otherwise. For example, selectively depositing a bitline metal stack on conductive bitline contacts relative to the insulating dielectric islands means that the bitline metal stack deposits on the conductive bitline contacts and less or no bitline metal stack deposits on the insulating dielectric islands; or that the formation of the bitline metal stack on the conductive bitline contacts is thermodynamically or kinetically favorable relative to the formation of the bitline metal stack on the insulating dielectric islands.

In the following description, numerous specific details, such as specific materials, chemistries, dimensions of the elements, etc. are set forth in order to provide thorough understanding of one or more of the embodiments of the present disclosure. It will be apparent, however, to one of ordinary skill in the art that the one or more embodiments of the present disclosure may be practiced without these specific details. In other instances, semiconductor fabrication processes, techniques, materials, equipment, etc., have not been described in great detail to avoid unnecessarily obscuring of this description. Those of ordinary skill in the art, with the included description, will be able to implement appropriate functionality without undue experimentation.

While certain exemplary embodiments of the disclosure are described and shown in the accompanying drawings, it is to be understood that such embodiments are merely illustrative and not restrictive of the current disclosure, and that this disclosure is not restricted to the specific constructions and arrangements shown and described because modifications may occur to those ordinarily skilled in the art.

In one or more embodiments, metal deposition and other processes can be carried out in an isolated environment (e.g., a cluster process tool). Accordingly, some embodiments of the disclosure provide integrated tool systems with related process modules to implement the methods described herein.

Embodiments of the present disclosure advantageously provide memory devices and methods of forming memory devices that have a reduced bitline metal stack thickness and a reduced bitline capacitance without increasing line resistance.

As described herein, the bitline metal stack comprises a metal and a barrier metal stack. Embodiments of the present disclosure include removing a portion of the bitline metal stack (e.g., the barrier metal stack) from the insulating dielectric islands under the bitline metal layer, which reduces the bitline metal stack thickness on the insulating dielectric islands. The portion of the bitline metal stack on the insulating dielectric islands is called a “passing bitline.” The total length of “passing bitline” is about half of a bitline. The passing bitline does not form conductive bitline contacts since there is no conductive path to access transistors. The metal can deposit and grow grain size directly on the insulating dielectric islands with low resistivity, and therefore, it is thought that there is no need for the barrier metal stack on top of the insulating dielectric islands. Therefore, as the overall thickness of bitline metal stack determines the bitline capacitance, the memory devices described herein (e.g., memory device 100, 200) have a reduced bitline metal stack thickness and a reduced bitline capacitance without reducing the metal thickness, which, in turn does not increase line resistance.

Embodiments of the present disclosure advantageously provide methods of modulating bitline capacitance and resistance. Advantageously, reduced bitline capacitance is obtained by providing the bitline metal stack described herein, while the thickness of the bitline metal remains the same and bitline resistance does not increase significantly.

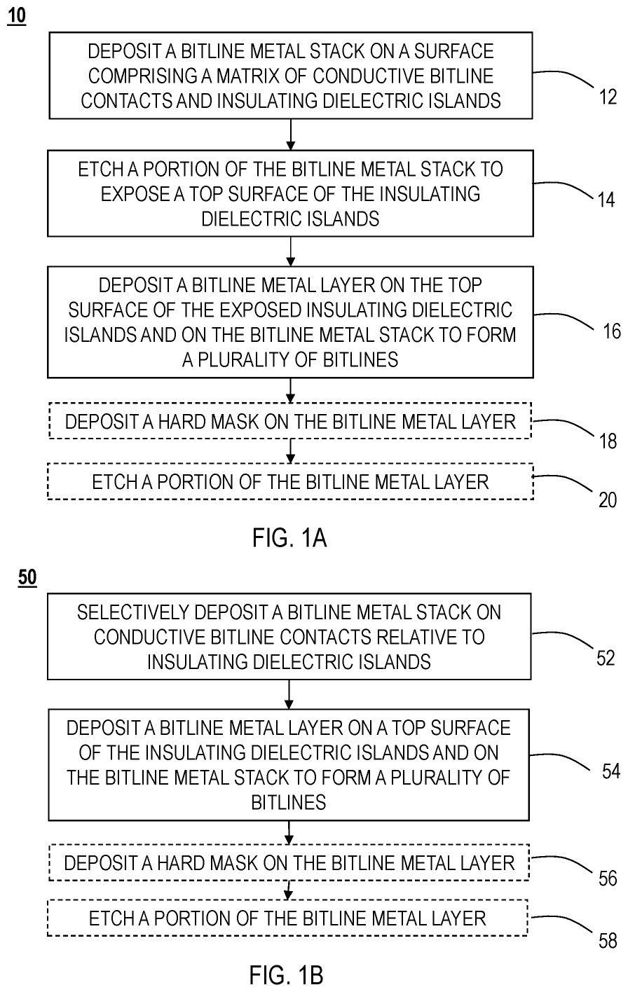

FIG. 1A illustrates a process flow diagram of a method 10 of forming a memory device. FIG. 1B illustrates a process flow diagram of a method 50 of forming a memory device. The skilled artisan will recognize that the methods described herein can include any or all of the processes illustrated.

With reference to FIG. 1A, the method 10 includes depositing a bitline metal stack on a surface comprising a matrix of conductive bitline contacts and insulating dielectric islands (operation 12); etching a portion of the bitline metal stack to expose a top surface of the insulating dielectric islands (operation 14); depositing a bitline metal layer on the top surface of the exposed insulating dielectric islands and on the bitline metal stack to form a plurality of bitlines (operation 16); optionally, depositing a hard mask on the bitline metal layer (operation 18); and optionally, etching a portion of the bitline metal layer (operation 20).

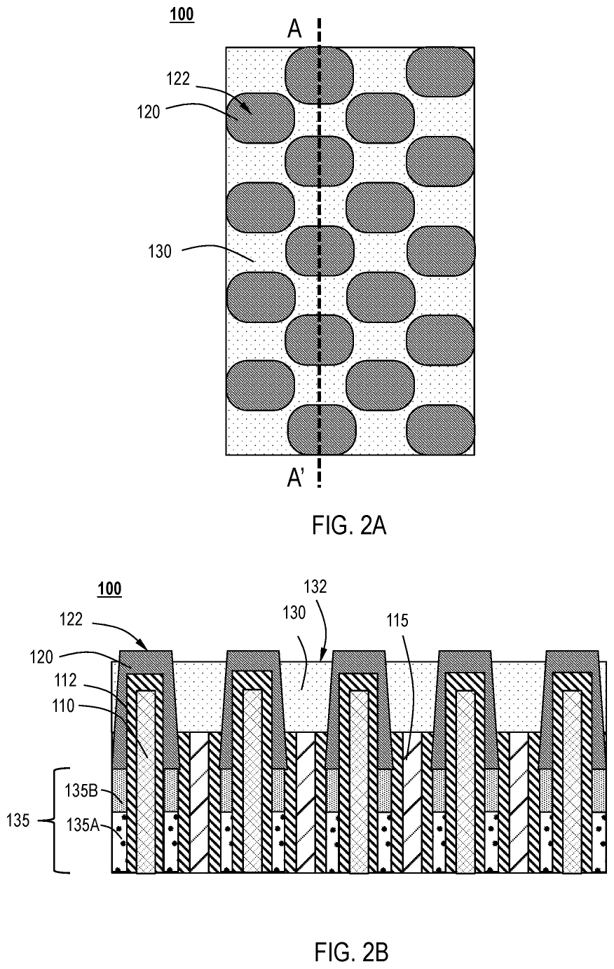

The manufacturing of a DRAM cell (e.g., memory device 100) includes the fabrication of a transistor, a capacitor, and contacts to the bitline and to the word line. In FIGS. 2A-6D, the memory device 100 includes an active area 115 which forms the source, drain, and channel of the DRAM cell. An array transistor is a switch that connects a storage node capacitor to the bitline. The wordline (WL) 135 is a gate of the array transistor. In some embodiments, the WL 135 comprises a first conductive material and a second conductive material on the first conductive material. In some embodiments, without intending to be bound by theory, a WL, such as WL 135 comprising a first conductive material and a second conductive material on the first conductive material is a dual work-function wordline that provides reduced access transistor leakage current.

A shallow trench isolation (STI) 110 insulates one active array transistor from an adjacent active array transistor. The STI 110 prevents adjacent active array transistors from short-circuiting each other. A conductive bitline contact 130 is the source/drain of the array transistor that connects to the bitline. The active area 115 under insulating dielectric islands 120 is the source/drain of the array transistor that connects to the storage node capacitor. The conductive bitline contact 130 is formed between insulating dielectric islands 120. In particular, embodiments of the disclosure provide memory devices and methods for forming memory devices having reduced bitline metal stack thickness and reduced bitline capacitance.

FIGS. 2A-6D illustrate a portion of a memory device 100 following the process flow diagram illustrated for the method 10 of FIG. 1A. FIGS. 2A and 2B illustrate an initial or starting memory device 100 in accordance with one or more embodiments of the disclosure. FIG. 2A illustrates a top view of the memory device 100. FIG. 2B illustrates a cross-sectional view of the memory device 100 of FIG. 2A taken along line A-A′.

FIG. 2B shows the memory device 100 comprising a plurality of wordlines (WLs) 135 comprises a first conductive material 135A and a second conductive material 135B on the first conductive material 135A. In some embodiments, without intending to be bound by theory, the WL 135 comprising the first conductive material 135A and the second conductive material 135B on the first conductive material 135A is a dual work-function wordline that provides reduced access transistor leakage current. In some embodiments, the first conductive material 135A comprises tungsten (W). In some embodiments, the second conductive material 135B comprises polysilicon. The memory device 100 includes a plurality of shallow trench isolations (STIs) 110, and each STI 110 insulates one active array transistor from an adjacent active array transistor. The STI 110 prevents adjacent active array transistors from short-circuiting each other. Each of the STIs 110 are insulated by a gate oxide material 112. The gate oxide material 112 may be any suitable gate oxide material known to the skilled artisan. The WL 135 is insulated from the STI 110 by the gate oxide material 112. In some embodiments, the gate oxide material insulates each active area 115. The conductive bitline contact 130 is the source/drain of the array transistor that connects to the bitline. A plurality of insulating dielectric islands 120 are formed on a top surface of the gate oxide material 112 that insulates each of the STIs 110. The active area 115 under insulating dielectric islands 120 is the source/drain of the array transistor that connects to the storage node capacitor. The conductive bitline contact 130 is formed between insulating dielectric islands 120 above the active area 115. The insulating dielectric islands 120 have a top surface 122. The conductive bitline contacts 130 has a top surface 132.

The STI 110 may include any suitable insulating dielectric material. In some embodiments, the STI 110 comprises one or more of silicon oxide (SiOx) or silicon nitride (SiN).

The active area 115 may include any suitable semiconductor material. In some embodiments, the active area 115 comprises one or more of crystalline silicon, monocrystalline silicon, polycrystalline silicon, germanium (Ge), silicon germanium (SiGe), gallium arsenide (GaAs), or indium gallium zinc oxide (IGZO).

The insulating dielectric islands 120 may include any suitable dielectric material. In some embodiments, the insulating dielectric islands 120 include one or more of silicon oxide (SiOx), silicon nitride (SIN), aluminum oxide (AlOx), hafnium oxide (HfOx), silicon oxycarbide (SiOC), silicon carbonitride (SiCN). In some embodiments, the insulating dielectric islands 120 comprise silicon nitride (SiN).

The conductive bitline contacts 130 may include any suitable conductive material. In some embodiments, the conductive bitline contacts 130 include one or more of polysilicon, conductively doped poly-SiGe, conductively doped poly-Ge, titanium nitride (TN), tantalum nitride (TaN), tungsten nitride (WN), tungsten (W), titanium (Ti), tantalum (Ta), molybdenum (Mo), cobalt (Co), or ruthenium (Ru), or alloys thereof. In some embodiments, the conductive bitline contacts 130 comprise polysilicon.

In one or more unillustrated embodiments, the method 10 comprises recessing a portion of the conductive bitline contacts 130 so that the conductive bitline contacts 130 have a height that is less than a height of the insulating dielectric islands 120 prior to depositing the bitline metal stack 140 at operation 12. In one or more unillustrated embodiments, the method 10 comprises recessing the top surface 132 of the conductive bitline contacts 130 so that the conductive bitline contacts 130 have a height that is less than a height of the insulating dielectric islands 120 prior to depositing the bitline metal stack 140 at operation 12. In some embodiments, the conductive bitline contacts 130 have a height that is less than a height of the insulating dielectric islands 120 prior to depositing the bitline metal stack 140 at operation 12, such that no recessing is required.

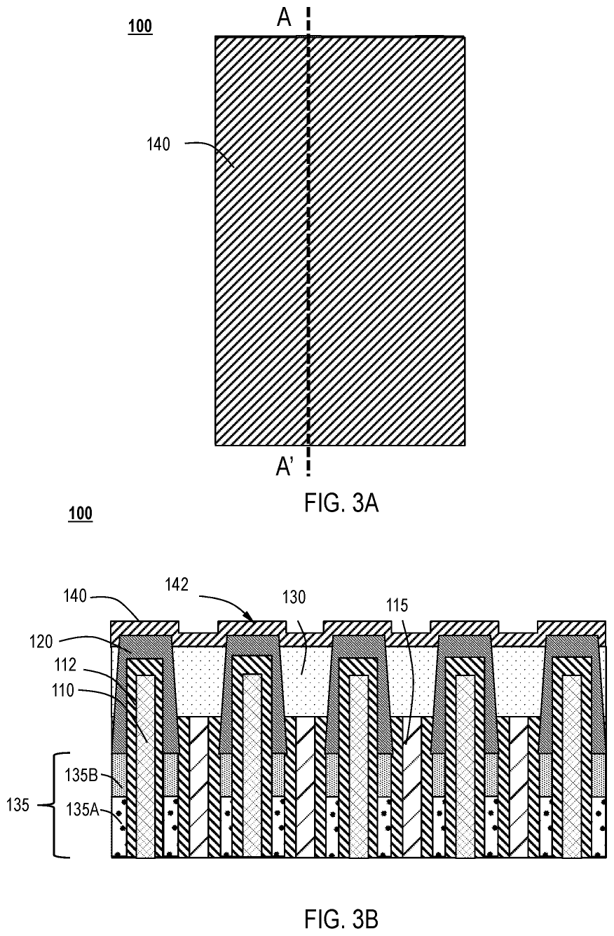

FIGS. 3A and 3B illustrate operation 12 of method 10: depositing a bitline metal stack 140 on the surface comprising the matrix of conductive bitline contacts 130 and insulating dielectric islands 120. FIG. 3A illustrates a top view of the memory device 100 and FIG. 3B illustrates a cross-sectional view of the memory device 100 of FIG. 3A taken along line A-A′.

In some embodiments, depositing the bitline metal stack 140 at operation 12 of the method 10 comprises a vapor deposition method. In some embodiments, the vapor deposition method comprises a physical vapor deposition (PVD) process or a variant thereof. In one or more embodiments, the bitline metal stack 140 is deposited by physical vapor deposition (PVD).

In one or more embodiments, the bitline metal stack 140 comprises a metal and a barrier metal stack. In one or more embodiments, the bitline metal stack 140 comprises one or more of titanium (Ti), tungsten (W), tungsten nitride (WN), tungsten silicide (WS), or tungsten silicon nitride (WSiN). In some embodiments, the bitline metal stack 140 comprises a barrier metal stack comprising one or more of titanium (Ti), tungsten nitride (WN), tungsten silicide (WS), or tungsten silicon nitride (WSiN).

In one or more embodiments, the bitline metal stack 140 has a first thickness in a range of from about 50 Å to about 100 Å prior to etching. In one or more embodiments, the first thickness of the bitline metal stack 140 is measured from a top surface 132 of the conductive bitline contact 130 to a top surface 142 of the bitline metal stack 140 in a z-direction.

In one or more embodiments, the bitline metal stack 140 has a second thickness in a range of from about 50 Å to about 100 Å prior to etching. In one or more embodiments, the second thickness of the bitline metal stack 140 is measured from the top surface of the insulating dielectric islands to the top surface 142 of the bitline metal stack 140 in a z-direction.

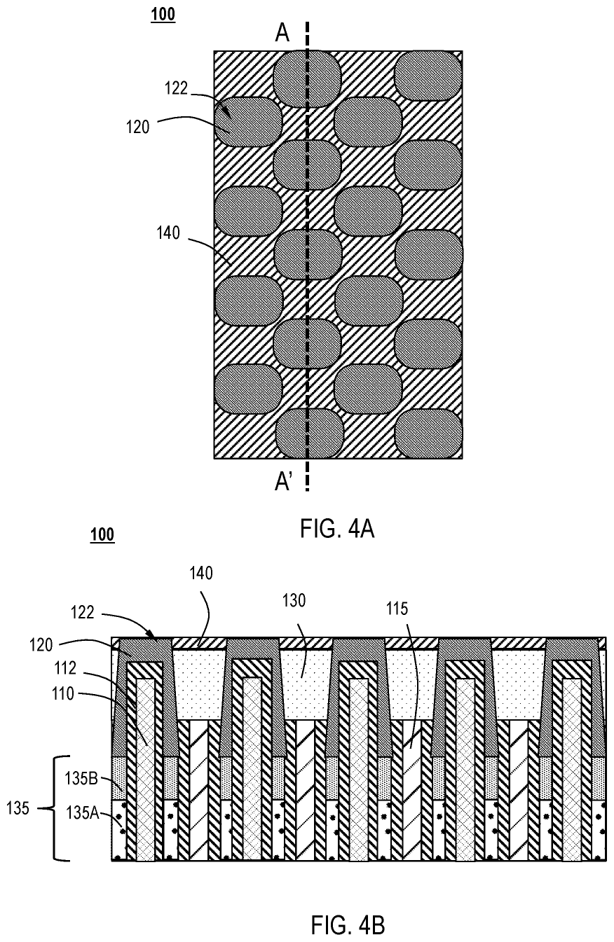

FIGS. 4A and 4B illustrate operation 14 of method 10: etching a portion of the bitline metal stack 140 to expose a top surface 122 of the insulating dielectric islands 120. In some embodiments, at operation 14, etching the portion of the bitline metal stack 140 to expose the top surface 122 of the insulating dielectric islands 120 forms exposed insulating dielectric islands 120. FIG. 4A illustrates a top view of the memory device 100 and FIG. 4B illustrates a cross-sectional view of the memory device of 100 FIG. 4A taken along the line A-A′.

In one or more embodiments, the first thickness of the bitline metal stack 140 remains the same etching. In one or more embodiments, the second thickness of the bitline metal stack 140 is reduced after etching. In some embodiments, the thickness of the bitline metal stack 140 on the top surface 122 of the insulating dielectric islands 120 (e.g., the second thickness) is less than or equal to 10Å, less than or equal to 5 Å, less than or equal to 2 Å, less than or equal to 1 Å, less than or equal to 0.5 Å, or less than or equal to 0.1 Å. In some embodiments, the top surface 122 of the insulating dielectric islands is free or substantially free of bitline metal stack 140. As used herein, the term “substantially free” means that the composition of the top surface 122 of the insulating dielectric islands less than less than about 5%, including less than about 4%, less than about 3%, less than about 2%, less than about 1%, and less than about 0.5% bitline metal stack 140.

The etching of operation 14 can be any suitable etching process or patterning process. In some embodiments, the etching of operation 14 includes a planarization process, for example a chemical mechanical polishing (CMP) process or an etchback process.

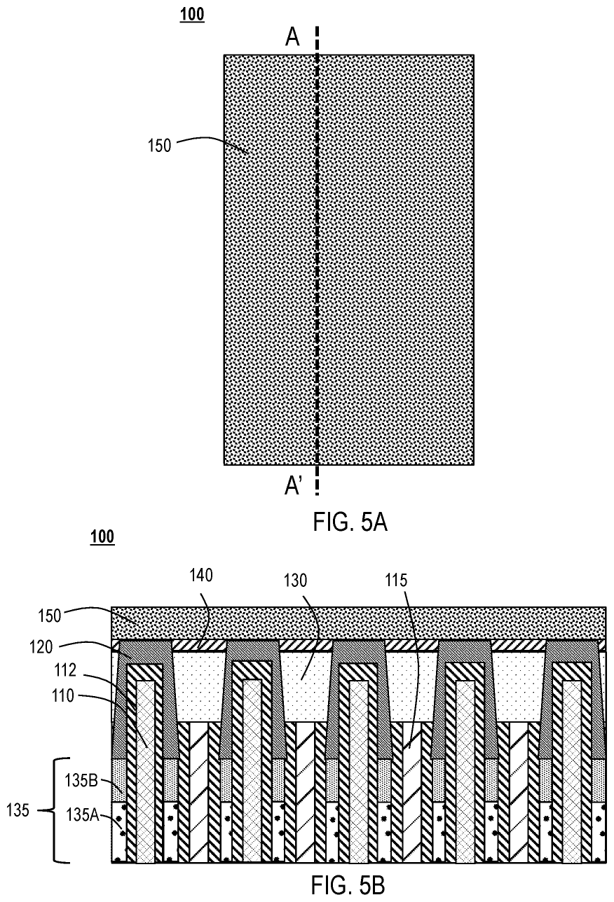

FIGS. 5A and 5B illustrate operation 16 of method 10: depositing a bitline metal layer 150 on the top surface 122 of the exposed insulating dielectric islands 120 and on the bitline metal stack 140 to form a plurality of bitlines. FIG. 5A illustrates a top view of the memory device 100 and FIG. 5B illustrates a cross-sectional view of the memory device 100 of FIG. 5A taken along the line A-A′.

In some embodiments, the bitline metal layer 150 comprises one or more of tungsten (W), molybdenum (Mo), tantalum (Ta), ruthenium (Ru), niobium (Nb), osmium (Os), zirconium (Zr), iridium (Ir), or rhenium (Re). In some embodiments, the bitline metal layer 150 comprises tungsten (W).

In some embodiments, the plurality of bitlines and the conductive bitline contacts 130 are self-aligned. In some embodiments, the plurality of bitlines and the conductive bitline contacts 130 are self-aligned as a result of a single dry etch step.

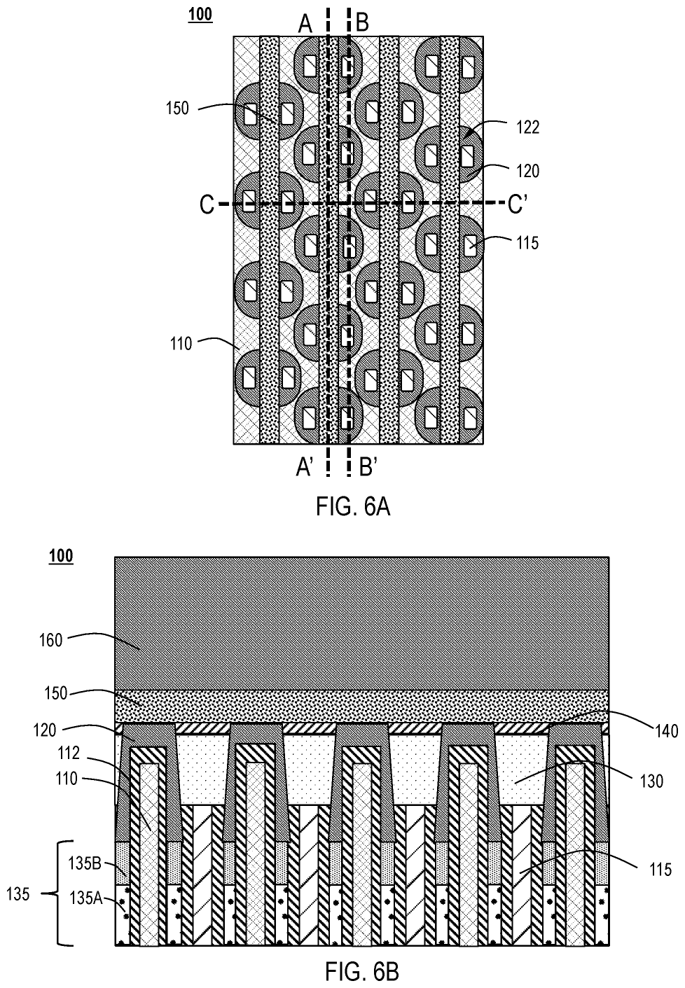

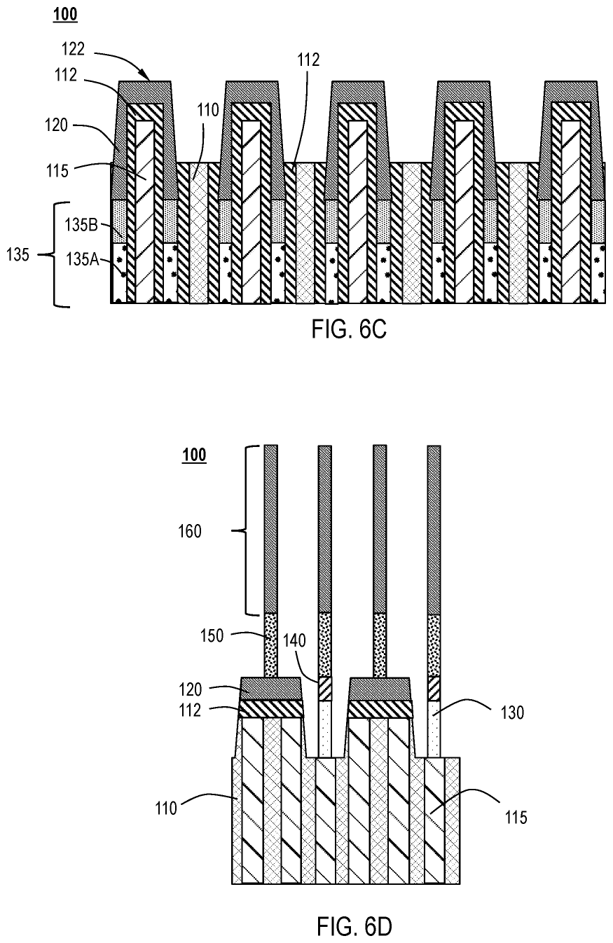

FIGS. 6A-6D illustrate optional operations 18 and 20 of method 10: depositing a hard mask 160 on the bitline metal layer 150 (operation 18) and etching a portion of the bitline metal layer 150 (operation 20). FIG. 6A illustrates a top view of the memory device 100. FIG. 6B illustrates a cross-sectional view of the memory device 100 of FIG. 6A taken along the line A-A′. FIG. 6C illustrates a cross-sectional view of the memory device 100 of FIG. 6A taken along the line B-B′. FIG. 6D illustrates a cross-sectional view of the memory device 100 of FIG. 6A taken along the line C-C′.

The hard mask 160 prevents damage and deformation of the bitline metal layer 150. In addition, the hard mask 160 may act as an etch mask in conjunction with conventional lithographic techniques to prevent the removal of the bitline metal layer 150 during etching.

The hard mask 160 may include any suitable dielectric material. In some embodiments, the hard mask 160 includes one or more of silicon oxide (SiOx), silicon nitride (SiN), aluminum oxide (AlOx), hafnium oxide (HfOx), silicon oxycarbide (SiOC), silicon carbonitride (SiCN). In some embodiments, the hard mask 160 comprises silicon nitride (SiN).

The hard mask 160 may be deposited on the bitline metal layer 150 by any suitable deposition process. In some embodiments, the hard mask 160 is deposited on the bitline metal layer 150 by chemical vapor deposition (CVD), physical vapor deposition (PVD), or atomic layer deposition (ALD). In some embodiments, the hard mask 160 is deposited on the bitline metal layer 150. The hard mask 160 may have any suitable thickness. In some embodiments, the hard mask 160 has a thickness in a range of from about 800 Å to about 1200 Å.

The etching of operation 20 may include the same process as the etching of operation 14. The etching of operation 20 can be any suitable etching process or patterning process. In some embodiments, the etching of operation 20 includes a planarization process, for example a chemical mechanical polishing (CMP) process or an etchback process.

In some embodiments, the memory device 100 comprises the bitline metal stack 140 on the surface comprising the matrix of conductive bitline contacts 130 and insulating dielectric islands 120. In some embodiments, the bitline metal stack 140 comprises one or more of titanium (Ti), tungsten (W), tungsten nitride (WN), tungsten silicide (WS), or tungsten silicon nitride (WSiN), and has a thickness in a range of from about 50 Å to about 100 Å. The memory device 100 further includes a bitline metal layer 150 on a top surface 122 of the insulating dielectric islands 120 and on the bitline metal stack 140. In some embodiments, the bitline metal layer 150 comprises tungsten (W) and has a thickness in a range of from about 150 Å to about 250 Å. In some embodiments, the memory device 100 includes a hard mask 160 on the bitline metal layer 150. In some embodiments, the hard mask 160 has a thickness in a range of from about 800 Å to about 1200 Å.

With reference to FIG. 1B, the method 50 includes selectively depositing a bitline metal stack on a surface comprising a matrix of conductive bitline contacts and insulating dielectric islands, the bitline metal stack selectively depositing on the conductive bitline contacts relative to the insulating dielectric islands (operation 52); depositing a bitline metal layer on a top surface of the insulating dielectric islands and on the bitline metal stack to form a plurality of bitlines (operation 54); optionally, depositing a hard mask on the bitline metal layer (operation 56); and optionally, etching a portion of the bitline metal layer (operation 58).

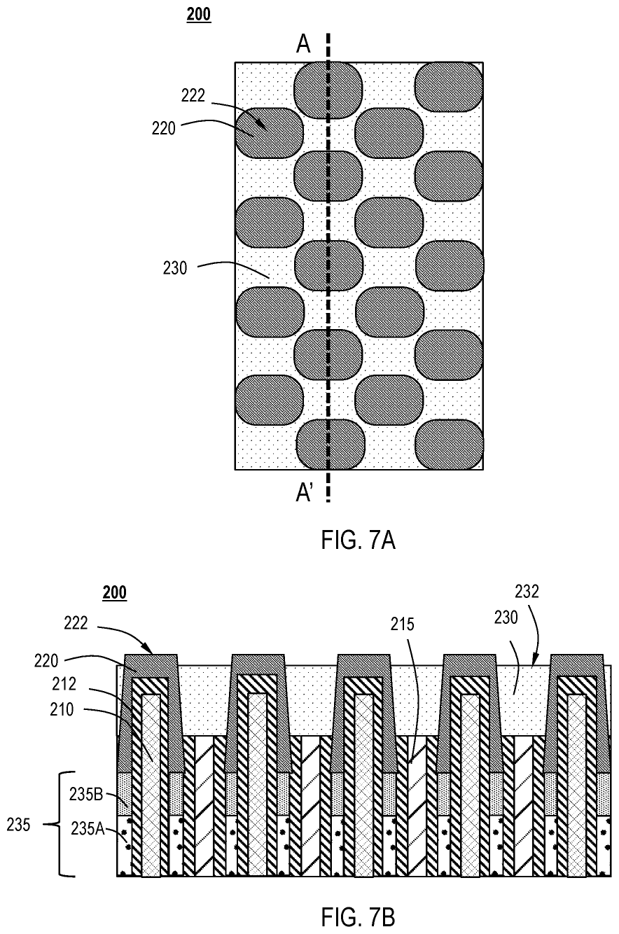

FIGS. 7A-10D illustrate a portion of a memory device 200 following the process flow diagram illustrated for the method 50 of FIG. 1B. FIGS. 7A and 7B illustrate an initial or starting memory device 200 in accordance with one or more embodiments of the disclosure. As used herein, like references indicate similar elements. For example, the active area 115 of memory device 100 corresponds to the active area 215 of memory device 200, unless the context specifically indicates otherwise.

FIG. 7B illustrates a cross-sectional view of the memory device 200 of FIG. 7A taken along the line A-A′. The memory device 200 shown in FIG. 7B comprises the same features as the memory device 100 shown in FIG. 2A.

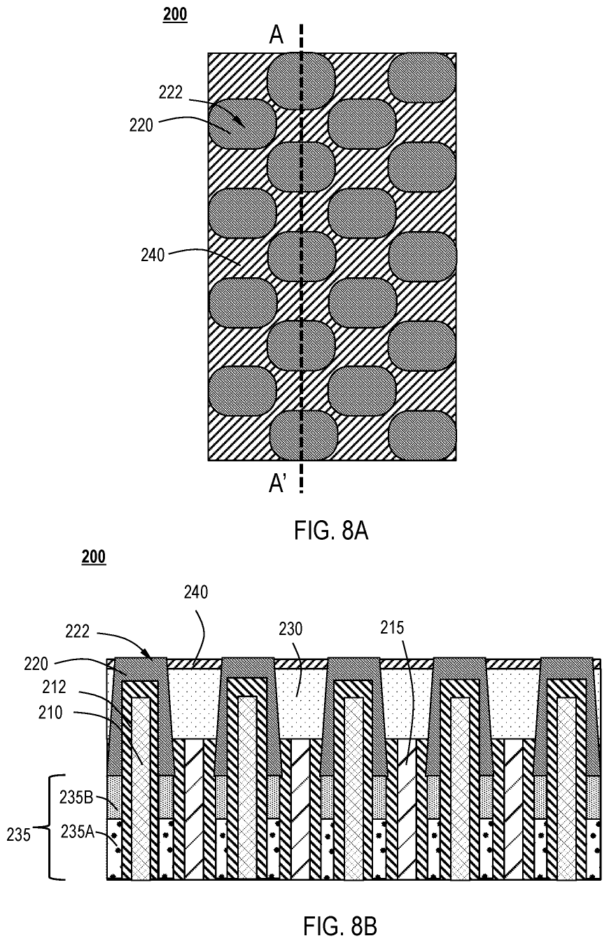

FIGS. 8A and 8B illustrate operation 52 of method 50: selectively depositing a bitline metal stack 240 on the conductive bitline contacts 230 relative to the insulating dielectric islands 220. FIG. 8A illustrates a top view of the memory device 200 and FIG. 8B illustrates a cross-sectional view of the memory device 200 of FIG. 8A taken along the line A-A′.

In some embodiments, at operation 52, selectively depositing the bitline metal stack 240 on the conductive bitline contacts 230 relative to the insulating dielectric islands 220 means that the bitline metal stack 240 deposits on the conductive bitline contacts 230 and less or no bitline metal stack 240 deposits on the insulating dielectric islands 220; or that the formation of the bitline metal stack 240 on the conductive bitline contacts 230 is thermodynamically or kinetically favorable relative to the formation of the bitline metal stack 240 on the insulating dielectric islands 220.

In one or more embodiments, the selective deposition of the bitline metal stack 240 on the conductive bitline contacts 230 relative to the insulating dielectric islands 220 is substantially conformal. As used herein, a layer which is “substantially conformal” refers to a layer where the thickness is about the same throughout (e.g., on the top surface 232 of each of the conductive bitline contacts 230). A layer which is substantially conformal varies in thickness by less than or equal to about 5%, 2%, 1% or 0.5%.

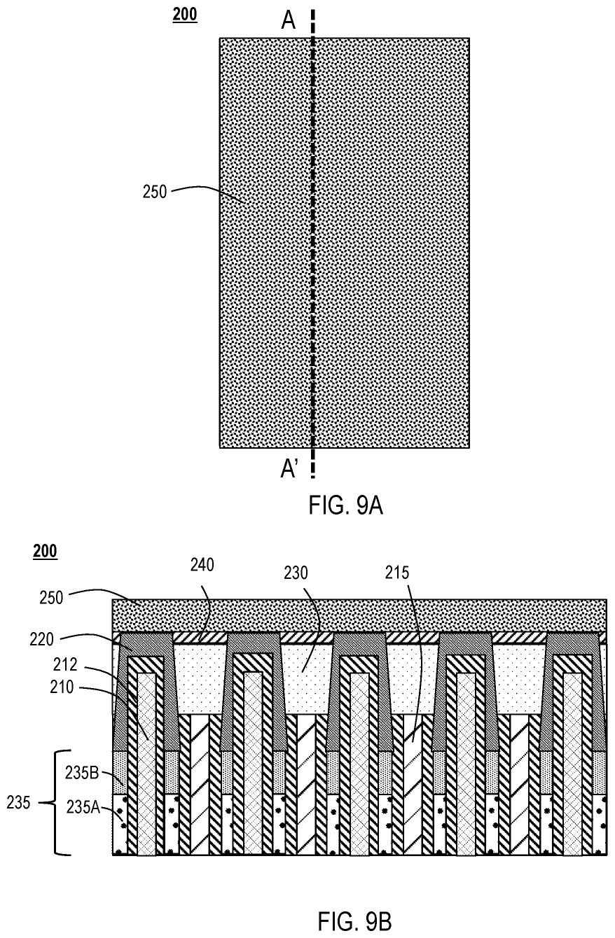

FIGS. 9A and B illustrate operation 54 of method 50: depositing a bitline metal layer 250 on the top surface 222 of the exposed insulating dielectric islands 220 and on the bitline metal stack 240 to form a plurality of bitlines. FIG. 9A illustrates a top view of the memory device 200 and FIG. 9B illustrates a cross-sectional view of the memory device 200 of FIG. 9A taken along the line A-A′. The bitline metal layer 250 may have the same properties as bitline metal layer 150 and may be deposited by the same process as operation 16 of method 10.

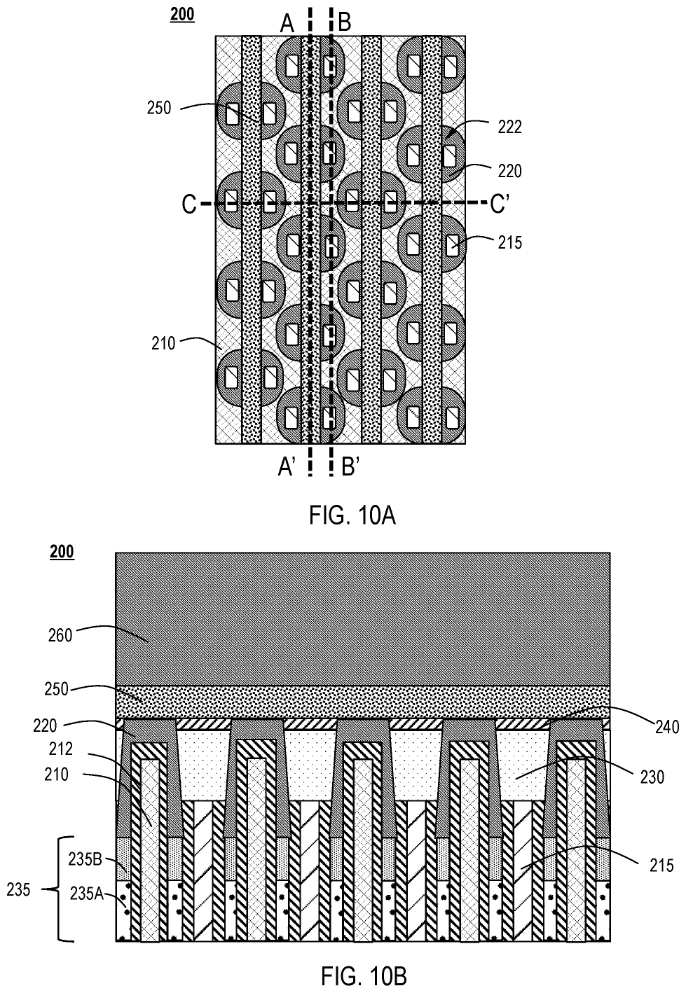

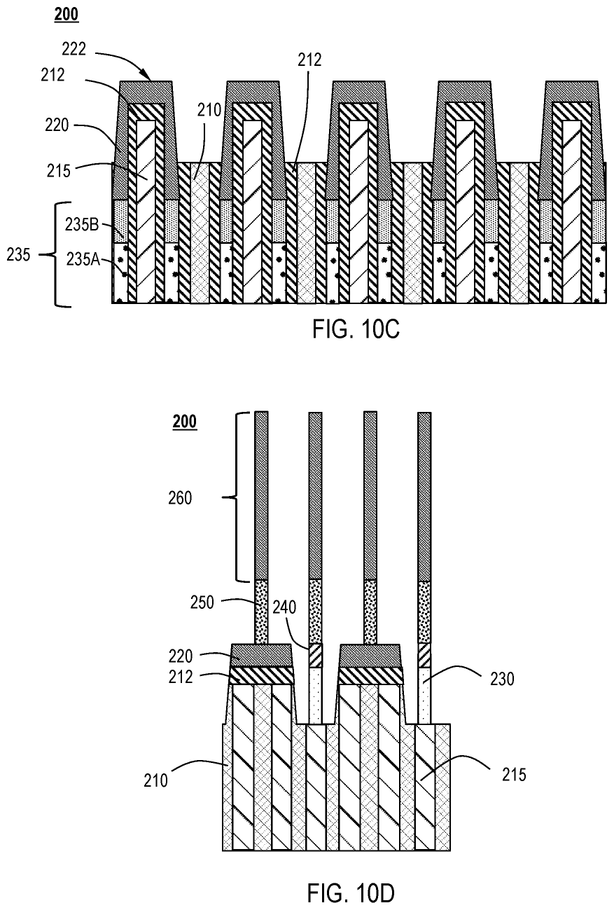

FIGS. 10A-10D illustrate optional operations 56 and 58 of method 50: depositing a hard mask 260 on the bitline metal layer 250 (operation 56) and etching a portion of the bitline metal layer 250 (operation 58). FIG. 10A illustrates a top view of the memory device 200. FIG. 10B illustrates a cross-sectional view of the memory device 200 of FIG. 10A taken along the line A-A′. FIG. 10C illustrates a cross-sectional view of the memory device 200 of FIG. 10A taken along the line B-B′. FIG. 10D illustrates a cross-sectional view of the memory device 200 of FIG. 10A taken along the line C-C′.

In some embodiments, the memory device 200 comprises the bitline metal stack 240 on the surface comprising the matrix of conductive bitline contacts 230 and insulating dielectric islands 220. In some embodiments, the bitline metal stack 240 comprises one or more of titanium (Ti), tungsten (W), tungsten nitride (WN), tungsten silicide (WS), or tungsten silicon nitride (WSiN), and has a thickness in a range of from about 50 Å to about 100 Å. The memory device 200 further includes a bitline metal layer 250 on a top surface 222 of the insulating dielectric islands 220 and on the bitline metal stack 240. In some embodiments, the bitline metal layer 250 comprises tungsten (W) and has a thickness in a range of from about 150 Å to about 250 Å. In some embodiments, the memory device 200 includes a hard mask 260 on the bitline metal layer 250. In some embodiments, the hard mask 260 has a thickness in a range of from about 800 Å to about 1200 Å.

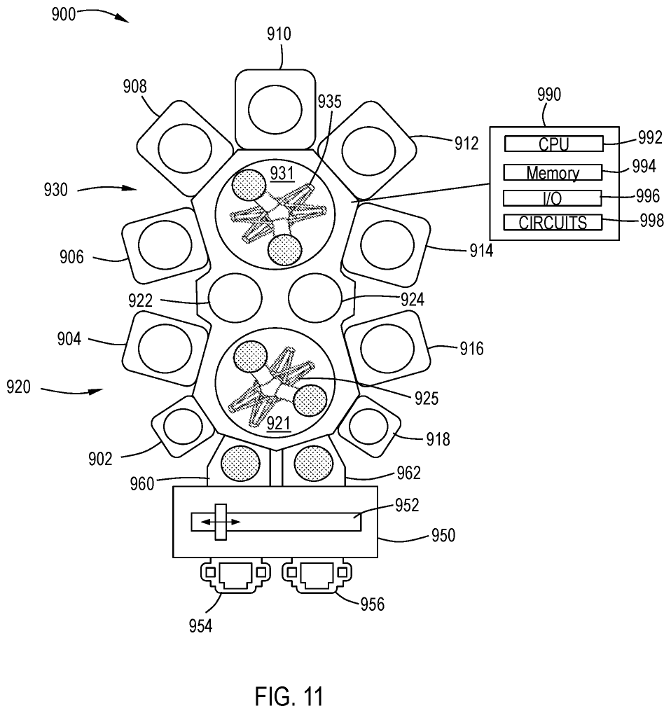

Additional embodiments of the disclosure are directed to cluster tools 900 for the formation of the memory devices and methods described, as shown in FIG. 11.

The cluster tool 900 includes at least one central transfer station 921, 931 with a plurality of sides. A robot 925, 935 is positioned within the central transfer station 921, 931 and is configured to move a robot blade and a wafer to each of the plurality of sides.

The cluster tool 900 comprises a plurality of processing chambers 902, 904, 906, 908, 910, 912, 914, 916, and 918, also referred to as process stations, connected to the central transfer station. The various processing chambers provide separate processing regions isolated from adjacent process stations. The processing chamber can be any suitable chamber including, but not limited to, a preclean chamber, a buffer chamber, transfer space(s), a wafer orienter/degas chamber, a cryo cooling chamber, a deposition chamber, annealing chamber, etching chamber, a selective oxidation chamber, an oxide layer thinning chamber, or a word line deposition chamber. The particular arrangement of process chambers and components can be varied depending on the cluster tool and should not be taken as limiting the scope of the disclosure.

In the embodiment shown in FIG. 11, a factory interface 950 is connected to a front of the cluster tool 900. The factory interface 950 includes a loading chamber 954 and an unloading chamber 956 on a front 951 of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the cluster tool 900. In the embodiment shown, the loading chamber 954 and unloading chamber 956 are sized to hold a wafer cassette with a plurality of wafers positioned within the cassette.

A robot 952 is within the factory interface 950 and can move between the loading chamber 954 and the unloading chamber 956. The robot 952 is capable of transferring a wafer from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock 962 and the unloading chamber 956.

The cluster tool 900 shown has a first section 920 and a second section 930. The first section 920 is connected to the factory interface 950 through load lock chambers 960, 962. The first section 920 includes a first transfer chamber 921 with at least one robot 925 positioned therein. The robot 925 is also referred to as a robotic wafer transport mechanism. The first transfer chamber 921 is centrally located with respect to the load lock chambers 960, 962, process chambers 902, 904, 916, 918, and buffer chambers 922, 924. The robot 925 of some embodiments is a multi-arm robot capable of independently moving more than one wafer at a time. In some embodiments, the first transfer chamber 921 comprises more than one robotic wafer transfer mechanism. The robot 925 in first transfer chamber 921 is configured to move wafers between the chambers around the first transfer chamber 921. Individual wafers are carried upon a wafer transport blade that is located at a distal end of the first robotic mechanism.

After processing a wafer in the first section 920, the wafer can be passed to the second section 930 through a pass-through chamber. For example, chambers 922, 924 can be uni-directional or bi-directional pass-through chambers. The pass-through chambers 922, 924 can be used, for example, to cryo cool the wafer before processing in the second section 930 or allow wafer cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit, memory, suitable circuits, and storage.

Processes may generally be stored in the memory of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

In one or more embodiments, a processing tool comprises: a central transfer station comprising a robot configured to move a wafer; a plurality of process stations, each process station connected to the central transfer station and providing a processing region separated from processing regions of adjacent process stations, the plurality of process stations comprising a deposition chamber, such as a physical vapor deposition (PVD) chamber and/or an atomic layer deposition (ALD) chamber; and a controller connected to the central transfer station and the plurality of process stations, the controller configured to activate the robot to move the wafer between process stations, and to control a process occurring in each of the process stations.

One or more embodiments provide a non-transitory computer readable medium including instructions, that, when executed by a controller of a processing chamber, causes the processing chamber to perform the operations of method 10. Further embodiments provide a non-transitory computer readable medium including instructions, that, when executed by a controller of a processing chamber, causes the processing chamber to perform the operations of method 50.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods, and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of forming a memory device, the method comprising:
depositing a bitline metal stack on a surface comprising a matrix of conductive bitline contacts and insulating dielectric islands;
etching a portion of the bitline metal stack to expose a top surface of the insulating dielectric islands; and
depositing a bitline metal layer on the top surface of the exposed insulating dielectric islands and on the bitline metal stack to form a plurality of bitlines.

2. The method of claim 1, wherein the bitline metal stack is deposited by physical vapor deposition (PVD).

3. The method of claim 1, wherein the bitline metal stack comprises one or more of titanium (Ti), tungsten (W), tungsten nitride (WN), tungsten silicide (WS), or tungsten silicon nitride (WSiN).

4. The method of claim 1, wherein the conductive bitline contacts comprise polysilicon.

5. The method of claim 1, wherein the insulating dielectric islands comprise one or more of an oxide and a nitride.

6. The method of claim 5, wherein the insulating dielectric islands comprise silicon nitride (SiN).

7. The method of claim 1, further comprising recessing a portion of the conductive bitline contacts so that the conductive bitline contacts have a height that is less than a height of the insulating dielectric islands prior to depositing the bitline metal stack.

8. The method of claim 1, wherein the bitline metal layer comprises one or more of tungsten (W), molybdenum (Mo), tantalum (Ta), ruthenium (Ru), niobium (Nb), osmium (Os), zirconium (Zr), iridium (Ir), or rhenium (Re).

9. The method of claim 8, further comprising etching a portion of the bitline metal layer.

10. The method of claim 1, wherein the plurality of bitlines and the conductive bitline contacts are self-aligned.

11. A method of forming a memory device, the method comprising:
selectively depositing a bitline metal stack on a surface comprising a matrix of conductive bitline contacts and insulating dielectric islands, the bitline metal stack selectively depositing on the conductive bitline contacts relative to the insulating dielectric islands; and
depositing a bitline metal layer on a top surface of the insulating dielectric islands and on the bitline metal stack to form a plurality of bitlines.

12. The method of claim 11, further comprising recessing a portion of the conductive bitline contacts so that the conductive bitline contacts have a height that is less than a height of the insulating dielectric islands prior to selectively depositing the bitline metal stack.

13. The method of claim 11, wherein the bitline metal stack comprises one or more of titanium (Ti), tungsten (W), tungsten nitride (WN), tungsten silicide (WS), or tungsten silicon nitride (WSiN).

14. The method of claim 11, wherein the conductive bitline contacts comprise polysilicon.

15. The method of claim 11, wherein the insulating dielectric islands comprise silicon nitride (SiN).

16. The method of claim 11, wherein the bitline metal layer comprises one or more of tungsten (W), molybdenum (Mo), tantalum (Ta), ruthenium (Ru), niobium (Nb), osmium (Os), zirconium (Zr), iridium (Ir), or rhenium (Re).

17. The method of claim 11, further comprising etching a portion of the bitline metal layer.

18. A memory device comprising:
a bitline metal stack on a surface comprising a matrix of conductive bitline contacts and insulating dielectric islands, the bitline metal stack comprising one or more of titanium (Ti), tungsten (W), tungsten nitride (WN), tungsten silicide (WS), or tungsten silicon nitride (WSiN), the bitline metal stack having a thickness in a range of from about 50 Å to about 100 Å; and
a bitline metal layer on a top surface of the insulating dielectric islands and on the bitline metal stack, the bitline metal layer comprising tungsten (W) and having a thickness in a range of from about 150 Å to about 250 Å.

19. The memory device of claim 18, wherein the conductive bitline contacts comprise polysilicon.

20. The memory device of claim 18, wherein the insulating dielectric islands comprise silicon nitride (SiN).
